(19) United States
(12) Patent Application Publication
(10) Pub. No.: US 2023/0336921 A1
(43) Pub. Date: Oct. 19, 2023

(54) ULTRASONIC GENERATOR, TRANSDUCER, AND OBJECT DETECTOR

(71) Applicant: AISIN CORPORATION, Kariya, Aichi (JP)

(72) Inventors: Ippei SUGAE, Kariya-shi, Aichi-ken (JP); Hisashi INABA, Kariya-shi, Aichi-ken (US)

(73) Assignee: AISIN CORPORATION, Kariya, Aichi (JP)

(21) Appl. No.: 18/028,095

(22) PCT Filed: Sep. 30, 2021
(86) PCT No.: PCT/JP2021/036290

§ 371 Date: Mar. 23, 2023

(30) Foreign Application Priority Data
Oct. 2, 2020 (JP) 2020-167922

(51) Int. Cl. H04R 17/00; H10N 30/20; H10N 30/80; H10N 30/87; G01S 7/521

(52) U.S. Cl. CPC H04R 17/00; H10N 30/20; H10N 30/802; H10N 30/87; G01S 7/521

(57) ABSTRACT

Provided is an apparatus including an ultrasonic generator including a transducer having a piezoelectric body that vibrates due to a piezoelectric effect and generates ultrasonic waves when an alternating voltage is applied, and three or more electrodes provided in different regions on a surface of the piezoelectric body. The apparatus includes a control unit that, when the control unit receives an ultrasonic wave generation instruction including information on a directivity of ultrasonic waves to be generated, selects from the three or more electrodes a combination of a voltage application electrode and a ground electrode corresponding to the directivity in the ultrasonic wave generation instruction and applies the alternating voltage to the voltage application electrode to generate ultrasonic waves, the voltage application electrode being an electrode to which the alternating voltage is to be applied, and the ground electrode being an electrode to be at a ground potential.

### CROSS REFERENCE TO RELATED APPLICATIONS

This application is a National Stage of International Application No. PCT/JP2021/036290 filed Sep. 30, 2021, claiming priority based on Japanese Patent Application No. 2020-167922 filed Oct. 2, 2020, the entire contents of which are incorporated in their entirety.

### TECHNICAL FIELD

The present disclosure relates to ultrasonic generators, transducers, and object detectors.

### BACKGROUND ART

Conventionally, there has been a technique of generate ultrasonic waves by applying an alternating voltage to a piezoelectric body to vibrate it by the piezoelectric effect. For example, one method to adjust the directivity of ultrasonic waves is to specially design a housing of a transducer (ultrasonic sensor).

The directivity of ultrasonic waves cannot be controlled (changed) by this method. For example, one method to control the directivity of ultrasonic waves is to use a plurality of transducers.

### RELATED ART DOCUMENTS

### Patent Documents

Patent Document 1: Japanese Unexamined Patent Application Publication No. 2001-289939 (JP 2001-289939 A)
Patent Document 2: Japanese Patent No. 4274679 (JP 4274679 B)
Patent Document 3: Japanese Patent No. 5513706 (JP 5513706 B)

### SUMMARY OF THE DISCLOSURE

### Problem to be Solved by Various Aspects of the Disclosure

However, using a plurality of transducers to control the directivity of ultrasonic waves is disadvantageous as it increases cost.

Therefore, it is one aspect of the present disclosure to implement, at low cost, an ultrasonic generator, transducer, and object detector that can generate ultrasonic waves by applying an alternating voltage to a piezoelectric body to vibrate the piezoelectric body and that can control the directivity of the ultrasonic waves.

### Means for Solving the Problem

An ultrasonic generator as an example of the present disclosure includes: a transducer including a piezoelectric body that vibrates due to a piezoelectric effect and generates ultrasonic waves when an alternating voltage is applied, and three or more electrodes provided in different regions on a surface of the piezoelectric body; and a control unit that, when the control unit receives an ultrasonic wave generation instruction including information on a directivity of ultrasonic waves to be generated, performs control to select from the three or more electrodes a combination of a voltage application electrode and a ground electrode corresponding to the directivity in the ultrasonic wave generation instruction and apply the alternating voltage to the voltage application electrode to generate ultrasonic waves, the voltage application electrode being an electrode to which the alternating voltage is to be applied, and the ground electrode being an electrode to be at a ground potential.

With this configuration, the directivity of the ultrasonic waves can be controlled by changing the combination of the voltage application electrode and the ground electrode out of the three or more electrodes. Therefore, the ultrasonic generator can be implemented at low cost.

The above ultrasonic generator further includes a storage unit that stores correspondence information between the combination of the voltage application electrode and the ground electrode out of the three or more electrodes and the directivity of the ultrasonic waves to be generated. The control unit performs control to refer to the correspondence information and generate the ultrasonic waves.

With this configuration, the combination of the voltage application electrode and the ground electrode corresponding to the directivity in the ultrasonic wave generation instruction can be selected from the three more electrodes by using the correspondence information stored in the storage unit.

In the above ultrasonic generator, the storage unit stores, as the correspondence information, the combination of the voltage application electrode and the ground electrode out of the three or more electrodes when ultrasonic waves with two or more directivities are to be generated and the two or more directivities. When the control unit receives an ultrasonic wave generation instruction including information on the two or more directivities of the ultrasonic waves to be generated, the control unit performs control to refer to the correspondence information, select from the three or more electrodes the combination of the voltage application electrode and the ground electrode corresponding to the two or more directivities in the ultrasonic wave generation instruction, and apply the alternating voltage to the voltage application electrode to generate ultrasonic waves with the two or more directivities.

With this configuration, the ultrasonic waves with the two or more directivities can be generated by selecting the combination of the voltage application electrode and the ground electrode from the three or more electrodes.

In the above ultrasonic generator, the control unit simultaneously transmits the ultrasonic waves with the two or more directivities.

With this configuration, the ultrasonic waves with the two or more directivities can be generated at the same time.

In the above ultrasonic generator, of the three or more electrodes, at least two electrodes are disposed on a first surface of the piezoelectric body, and at least one electrode is disposed on a second surface opposing the first surface. The control unit selects at least one of the electrodes disposed on the first surface as the voltage application electrode, and selects the electrode disposed on the second surface as the ground electrode. The control unit controls the directivity of the ultrasonic waves to be generated by switching the electrode that serves as the voltage application electrode among the electrodes disposed on the first surface.

With this configuration, since the electrodes are disposed on the two opposing surfaces, the directivity can be more easily controlled and design cost can be reduced as compared to the case where the electrodes are disposed on three or more surfaces.

A transducer as an example of the present disclosure includes: a piezoelectric body that vibrates due to a piezoelectric effect and generates ultrasonic waves when an alternating voltage is applied; and three or more electrodes provided in different regions on a surface of the piezoelectric body. A directivity of the ultrasonic waves that are generated is different depending on a selected combination of a voltage application electrode and a ground electrode, the voltage application electrode being an electrode to which the alternating voltage is to be applied, and the ground electrode being an electrode to be at a ground potential.

With this configuration, the transducer that can control the directivity of the ultrasonic waves by changing the combination of the voltage application electrode and the ground electrode out of the three or more electrodes can be implemented at low cost.

An object detector as an example of the present disclosure is an object detector in which a transmission unit transmits ultrasonic waves from a transducer and a reception unit receives reflected waves of the ultrasonic waves by the transducer. The transducer includes a piezoelectric body that vibrates due to a piezoelectric effect and generates ultrasonic waves when an alternating voltage is applied, and three or more electrodes provided in different regions on a surface of the piezoelectric body. A directivity of the ultrasonic waves that are generated is different depending on a selected combination of a voltage application electrode and a ground electrode, the voltage application electrode being an electrode to which the alternating voltage is to be applied, and the ground electrode being an electrode to be at a ground potential. The transmission unit includes a switching unit that changes the combination of the voltage application electrode and the ground electrode. The reception unit includes an amplifier circuit and a filtering unit. The filtering unit acquires information on a frequency of a transmission signal, and performs correction of a frequency of a reception signal so as to match the frequency of the transmission signal.

With this configuration, the object detector that can control the directivity of the ultrasonic waves by changing the combination of the voltage application electrode and the ground electrode out of the three or more electrodes can be implemented at low cost.

The above object detector includes a storage unit that stores correspondence information between the combination of the voltage application electrode and the ground electrode out of the three or more electrodes and the directivity of the ultrasonic waves to be generated. The transmission unit refers to the correspondence information and controls the switching unit to transmit the ultrasonic waves from the transducer.

With this configuration, the combination of the voltage application electrode and the ground electrode corresponding to a directivity in an ultrasonic wave generation instruction can be selected from the three more electrodes by using the correspondence information stored in the storage unit.

In the above object detector, the storage unit stores, as the correspondence information, the combination of the voltage application electrode and the ground electrode out of the three or more electrodes when ultrasonic waves with two or more directivities are to be generated and the two or more directivities. When the transmission unit receives an ultrasonic wave generation instruction including information on the two or more directivities of the ultrasonic waves to be generated, the transmission unit refers to the correspondence information, selects from the three or more electrodes the combination of the voltage application electrode and the ground electrode corresponding to the two or more directivities in the ultrasonic wave generation instruction, controls the switching unit to apply the alternating voltage to the voltage application electrode to generate the ultrasonic waves with the two or more directivities, and transmits the ultrasonic waves from the transducer.

With this configuration, the ultrasonic waves with the two or more directivities can be generated by selecting the combination of the voltage application electrode and the ground electrode from the three or more electrodes.

In the above object detector, the transmission unit performs control to generate ultrasonic waves with two or more directivities by making at least one of a frequency, a phase, and an amplitude of the ultrasonic waves different from each other. When the reception unit detects ultrasonic waves via the transducer immediately thereafter, the reception unit identifies which of the ultrasonic waves of the two or more directivities are the original ultrasonic waves of reflected waves, based on the frequency, the phase, or the amplitude of the detected ultrasonic waves, whichever has been made different.

With this configuration, when reflected waves of the ultrasonic waves with the two or more directivities are detected, which of the ultrasonic waves with the two or more directivities are the original ultrasonic waves of the reflected waves can be identified based on the frequency, the phase, or the amplitude.

In the above object detector, the transmission unit simultaneously transmits the ultrasonic waves with the two or more directivities. When the reception unit detects ultrasonic waves via the transducer immediately thereafter, the reception unit identifies which of the ultrasonic waves of the two or more directivities are the original ultrasonic waves of reflected waves, based on the frequency, the phase, or the amplitude of the detected ultrasonic waves, whichever has been made different.

With this configuration, the ultrasonic waves with the two or more directivities can be generated at the same time.

### BRIEF DESCRIPTION OF THE DRAWINGS

FIG. 1 is a schematic diagram of the appearance of a vehicle equipped with an object detection system of a first embodiment as viewed from above.

FIG. 2 is a block diagram schematically showing general hardware configurations of an ECU and an object detector of the first embodiment.

FIG. 3 is a schematic diagram showing a general view of a transducer of the first embodiment.

FIG. 4 is an illustration of the directivity of ultrasonic waves generated from the transducer of the first embodiment.

FIG. 5 is a general illustration of a technique that is used by the object detector of the first embodiment to detect the distance to an object.

FIG. 6 is a block diagram schematically showing a detailed configuration of the object detector of the first embodiment.

FIG. 7 is a diagram showing directivity correspondence information of the first embodiment.

FIG. 8 is a flowchart showing a process that is performed by the object detection system of the first embodiment.

FIG. 9 is a diagram showing transmission wave correspondence information of a second embodiment.

### DESCRIPTION OF EMBODIMENTS

Hereinafter, embodiments (first embodiment, second embodiment) of the present disclosure will be described with reference to the drawings. The configurations of the embodiments described below and the functions and effects obtained by these configurations are merely illustrative, and the present invention is not limited to the following description.

### First Embodiment

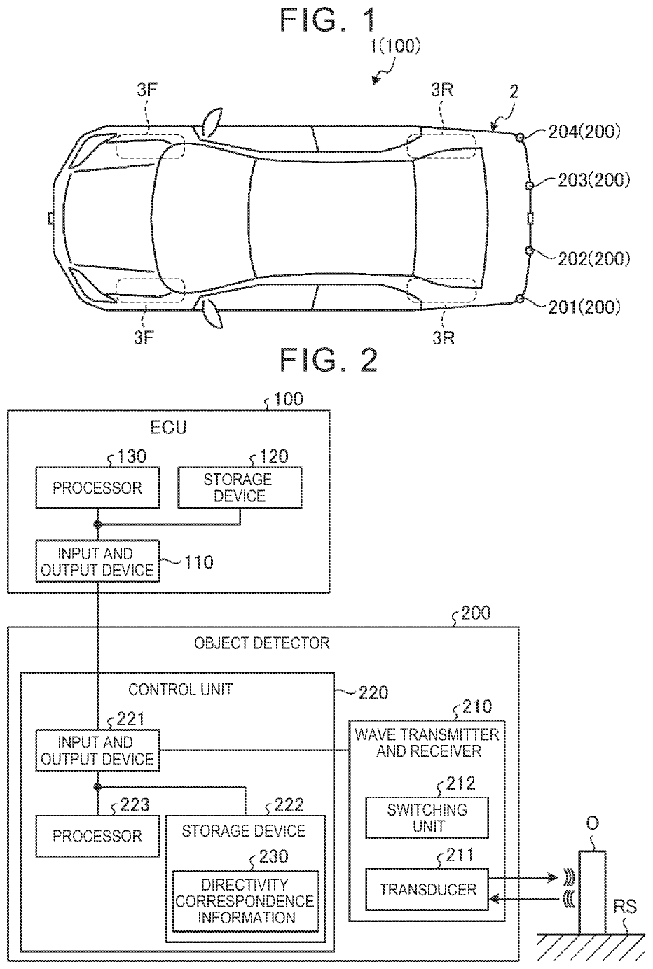

FIG. 1 is a schematic diagram of the appearance of a vehicle equipped with an object detection system of a first embodiment as viewed from above. The object detection system of the first embodiment is an in-vehicle sensor system that transmits and receives ultrasonic waves and detects objects present in the surroundings (e.g., an obstacle O shown in FIG. 2 that will be described later) by using the time lag between the transmission and reception etc.

More specifically, as shown in FIG. 1, the object detection system of the first embodiment includes an electronic control unit (ECU) 100 as an in-vehicle control device and object detectors 201 to 204 as in-vehicle sonars. The ECU 100 is mounted inside a four-wheeled vehicle 1 including a pair of front wheels 3F and a pair of rear wheels 3R, and the object detectors 201 to 204 are mounted on an exterior part of the vehicle 1.

In the example shown in FIG. 1, as an example, the object detectors 201 to 204 are installed at different positions on a rear end portion (rear bumper) of a vehicle body 2 as an exterior part of the vehicle 1. The installation positions of the detectors 201 to 204 are not limited to the example shown in FIG. 1. For example, the object detectors 201 to 204 may be installed on a front end portion (front bumper) of the vehicle body 2, may be installed on side surface portions of the vehicle body 2, or may be installed on two or more of the following portions: the rear end portion, the front end portion, and the side surface portions.

In the first embodiment, the object detectors 201 to 204 have the same hardware configuration and functions. Therefore, the object detectors 201 to 204 are hereinafter sometimes collectively referred to as “object detectors 200” (example of the ultrasonic generator) for simplicity of description. In the first embodiment, the number of object detectors 200 is not limited to four as shown in FIG. 1.

FIG. 2 is a block diagram schematically showing general hardware configurations of the ECU 100 and the object detector 200 of the first embodiment.

As shown in FIG. 2, the ECU 100 has a hardware configuration similar to that of a normal computer. More specifically, the ECU 100 includes an input and output device 110, a storage device 120, and a processor 130.

The input and output device 110 is an interface for implementing transmission and reception of information between the ECU 100 and the outside (object detectors 200 in the example shown in FIG. 1).

The storage device 120 includes a main storage device such as a read only memory (ROM) and a random access memory (RAM) and/or an auxiliary storage device such as a hard disk drive (HDD) and a solid state drive (SSD).

The processor 130 controls various processes that are performed in the ECU 100. The processor 130 includes an arithmetic unit such as, for example, a central processing unit (CPU). The processor 130 implements various functions such as automatic parking by reading and executing computer programs stored in the storage device 120.

As shown in FIG. 2, the object detector 200 includes a wave transmitter and receiver 210 and a control unit 220.

The wave transmitter and receiver 210 has a transducer 211 (example of the ultrasonic sensor) composed of a piezoelectric element etc., and a switching unit 212, and the transducer 211 transmits and receives ultrasonic waves.

More specifically, the wave transmitter and receiver 210 transmits ultrasonic waves generated as the transducer 211 vibrates as transmission waves, and receives vibration of the transducer 211 caused as the ultrasonic waves transmitted as the transmission waves are reflected back from an object present outside as reception waves. In the example shown in FIG. 2, the obstacle O installed on a road surface RS is illustrated as an object that reflects ultrasonic waves transmitted from the wave transmitter and receiver 210.

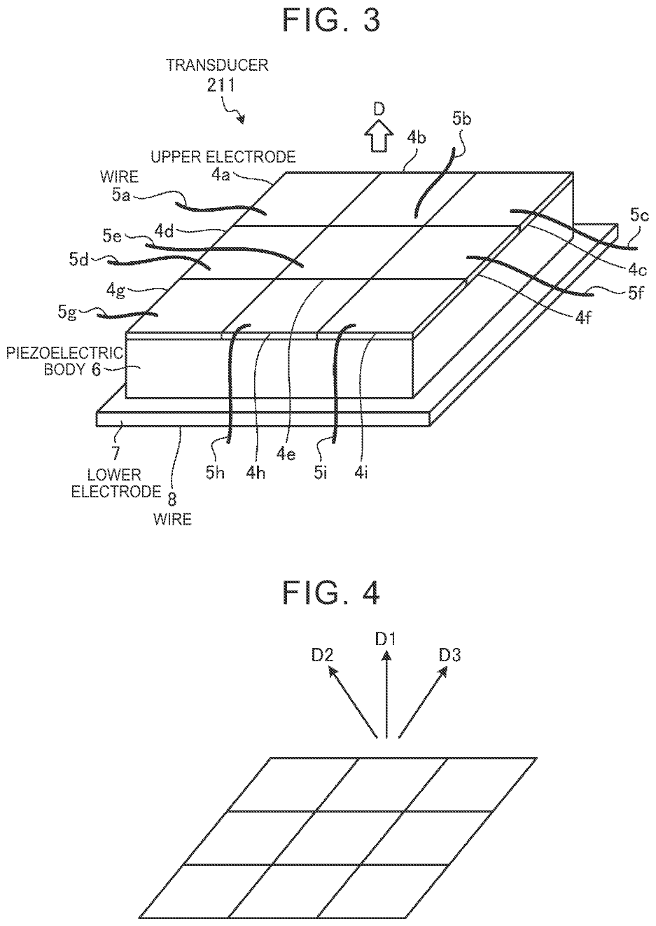

FIG. 3 is a schematic diagram showing a general view of the transducer 211 of the first embodiment. The transducer 211 includes nine (3×3) upper electrodes 4a to 4i (electrodes disposed on a first surface), wires 5a to 5i, a piezoelectric body 6, a lower electrode 7 (electrode disposed on a second surface), and a wire 8. The nine upper electrodes 4a to 4i and the lower electrode 7 are an example of the three or more electrodes, and are hereinafter sometimes collectively referred to as “ten electrodes.” The wires 5a to 5i and the wire 8 are also sometimes referred to as “ten wires.”

The nine upper electrodes 4a to 4i are provided in different regions on the upper surface of the piezoelectric body 6 and are electrically insulated from each other. The wires 5a to 5i are provided for the upper electrodes 4a to 4i, respectively.

When an alternating voltage is applied to the piezoelectric body 6, the piezoelectric body 6 vibrates due to the piezoelectric effect and generates ultrasonic waves.

The lower electrode 7 is provided on the lower surface of the piezoelectric body 6. The wire 8 is provided for the lower electrode 7.

That is, the example of FIG. 3 is an example of the case where, of the three or more electrodes, at least two electrodes are disposed on the first surface of the piezoelectric body 6 and at least one electrode is disposed on the second surface opposing the first surface. In this case, a processor 223 selects at least one of the electrodes disposed on the first surface as a voltage application electrode, and selects the electrode disposed on the second surface as a ground electrode. The processor 223 controls the directivity of ultrasonic waves to be generated by switching the electrode serving as a voltage application electrode among the electrodes disposed on the first surface (this will be described in detail later).

Referring back to FIG. 2, the control unit 220 has a hardware configuration similar to that of a normal computer. More specifically, the control unit 220 includes an input and output device 221, a storage device 222, and the processor 223.

The input and output device 221 is an interface for implementing transmission and reception of information between the control unit 220 and the outside (ECU 100 and wave transmitter and receiver 210 in the example shown in FIG. 1).

The storage device 222 includes a main storage device such as ROM and RAM and/or an auxiliary storage device such as HDD and SSD. The storage device 222 stores, for example, directivity correspondence information 230. The directivity correspondence information 230 is an example of correspondence information between the combination of a voltage application electrode that is an electrode to which an alternating voltage is to be applied and a ground electrode that is an electrode to be at the ground potential out of the ten electrodes and the directivity of ultrasonic waves to be generated.

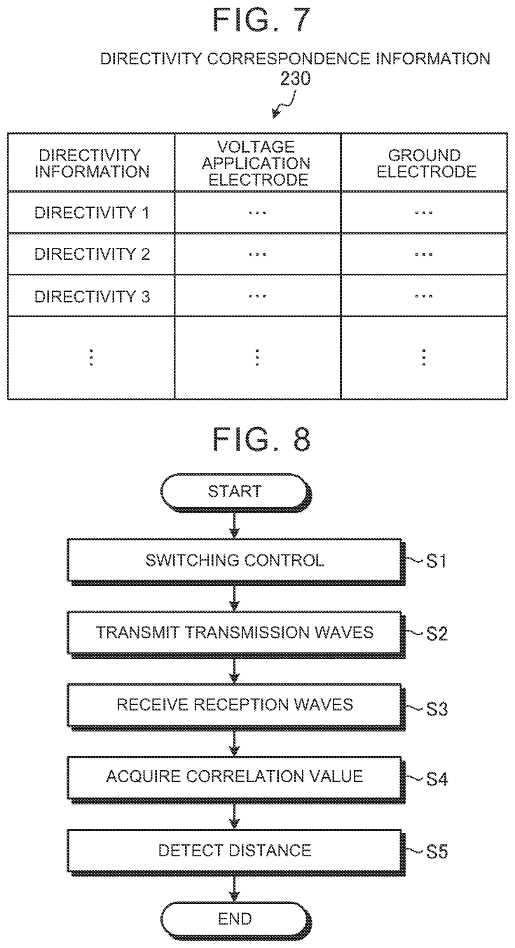

FIG. 7 is a diagram showing the directivity correspondence information 230 of the first embodiment. In the directivity correspondence information 230, a combination of a voltage application electrode and a ground electrode is associated with each piece of directivity information that is information on the direction in which ultrasonic waves are output and the way they spread. One possible example is a combination of the upper electrode 4a (FIG. 3) as a voltage application electrode and the remaining nine electrodes as ground electrodes. When the combination of a voltage application electrode and a ground electrode is different, the way a voltage is applied to the piezoelectric body 6 will be different and the part of the piezoelectric body 6 that vibrates will be different, so that the directivity of ultrasonic waves generated from the piezoelectric body 6 will also be different. The number of ground electrodes may be two or more, or may be one. The electrodes other than a voltage application electrode and a ground electrode are insulated.

The output direction of ultrasonic waves generated from the transducer 211 is roughly the direction shown by character D in FIG. 3. FIG. 4 is an illustration of the directivity of ultrasonic waves generated from the transducer of the first embodiment. Depending on the combination of a voltage application electrode and a ground electrode, the direction in which ultrasonic waves generated from the piezoelectric body 6 are output can change to various directions as illustrated by characters D1 to D3. The way the ultrasonic waves spread can also vary in various manners. For example, the directivity correspondence information 230 as shown in FIG. 7 can be created in advance through experiments.

Referring back to FIG. 2, the processor 223 controls various processes that are performed in the control unit 220. The processor 223 includes an arithmetic unit such as, for example, a CPU. The processor 223 implements various functions by reading and executing computer programs stored in the storage device 222.

For example, when the processor 223 receives from the ECU 100 an ultrasonic wave generation instruction including information on the directivity of ultrasonic waves to be generated, the processor 223 performs control to refer to the directivity correspondence information 230, select from the ten electrodes a combination of a voltage application electrode and a ground electrode corresponding to the directivity in the ultrasonic wave generation instruction, and apply an alternating voltage to the voltage application electrode to generate ultrasonic waves.

When a combination of a voltage application electrode and a ground electrode is determined, the switching unit 212 performs switching to connect the wire corresponding to the voltage application electrode out of the ten wires to a power supply, performs switching to connect the wire corresponding to the ground electrode to the ground, and perform switching to insulate the other wires, as instructed by the processor 223.

The object detector 200 of the first embodiment detects the distance to an object using a so-called time-off-light (TOF) technique. The TOF technique is a technique of calculating the distance to an object by taking into consideration the difference between the time when transmission waves are transmitted (more specifically, when transmission waves start to be transmitted) and the time when reception waves are received (more specifically, when reception waves start to be received).

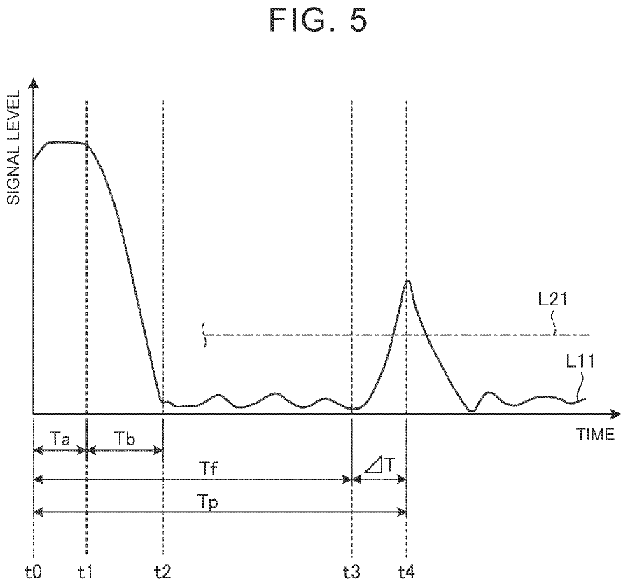

FIG. 5 is a general illustration of the technique that is used by the object detector 200 of the first embodiment to detect the distance to an object. More specifically, FIG. 5 is a diagram illustratively and schematically showing in the form of a graph a change over time in signal level (e.g., amplitude) of ultrasonic waves that are transmitted and received by the object detector 200 of the first embodiment. In the graph shown in FIG. 5, the abscissa represents time, and the ordinate represents the signal level of a signal that is transmitted and received by the object detector 200 via the wave transmitter and receiver 210 (transducer 211).

In the graph shown in FIG. 5, a solid line L11 shows an example of an envelope representing a change over time in signal level of a signal that is transmitted and received by the object detector 200, that is, in extent of vibration of the transducer 211. It can be seen from this solid line L11 that, as the transducer 211 is driven to vibrate for a time period Ta from time t0, transmission of transmission waves is completed at time t1, and thereafter the vibration of the transducer 211 continues while attenuating for a time period Tb until time t2. Therefore, in the graph shown in FIG. 5, the time period Tb corresponds to so-called reverberation time.

In solid line L11, the extent of vibration of the transducer 211 reaches a peak higher than a predetermined threshold Th1 represented by long dashed short dashed line L21 at time t4 that is a time period Tp after time t0 at which transmission of transmission waves is started. This threshold Th1 is a value set in advance in order to identify whether the vibration of the transducer 211 has been caused by reception of reception waves that are transmission waves reflected back from an object to be detected (e.g., the obstacle O shown in FIG. 2) or has been caused by reception of reception waves that are transmission waves reflected back from an object other than the object to be detected (e.g., the road surface RS shown in FIG. 2).

FIG. 5 shows an example in which the threshold Th1 is set as a constant value that does not change over time. However, in the first embodiment, the threshold Th1 may be set as a value that changes over time.

Vibration having a peak higher than the threshold Th1 can be considered to have been caused by reception of reception waves that are transmission waves reflected back from an object to be detected. Vibration having a peak equal to or less than the threshold Th1 can be considered to have been caused by reception of reception waves that are transmission waves reflected back from an object other than the object to be detected.

Therefore, it can be seen from solid line L11 that the vibration of the transducer 211 at time t4 was caused by reception of reception waves that are transmission waves reflected back from an object to be detected.

In solid line L11, the vibration of the transducer 211 attenuates after time t4. Therefore, time t4 corresponds to the time when reception of reception waves that are transmission waves reflected back from an object to be detected is completed, in other words, the time when the last transmission wave transmitted at time t1 returns as a reception wave.

In solid line L11, time t3 that is the starting point of the peak at time t4 corresponds to the time when reception of reception waves that are transmission waves reflected back from an object to be detected starts, in other words, the time when the first transmission wave transmitted at time t0 returns as a reception wave. Therefore, in solid line L11, a time period ΔT between time t3 and time t4 is equal to the time period Ta that is the transmission time of transmission waves.

Based on the above, in order to obtain the distance to an object to be detected by the TOF technique, it is necessary to obtain a time period tf between time t0 when transmission waves start to be transmitted and time t3 when reception waves start to be received. This time period tf can be obtained by subtracting the time period ΔT equal to the time period to that is the transmission time of transmission waves from the time period t0 that is the difference between time t0 and time t4 at which the signal level of reception waves reaches a peak higher than the threshold Th1.

It is sometimes desired to control (change) the directivity of ultrasonic waves to be generated from the transducer 211, such as when identifying whether an object that has reflected ultrasonic waves is an object to be detected (e.g., the obstacle O shown in FIG. 2) or an object other than the object to be detected (e.g., the road surface RS shown in FIG. 2).

However, using a plurality of ultrasonic sensors to control the directivity of ultrasonic waves is disadvantageous as it increases cost. Therefore, in the first embodiment, the directivity of ultrasonic waves is controlled by a single ultrasonic sensor (transducer 211), thereby implementing low cost.

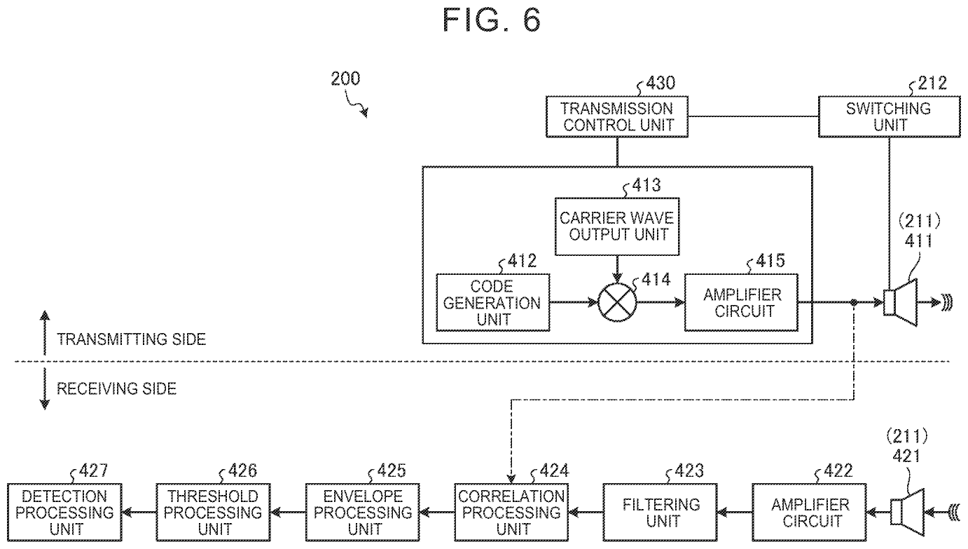

FIG. 6 is a block diagram schematically showing a detailed configuration of the object detector 200 of the first embodiment. In FIG. 6, the configuration of the transmitting side (transmission unit) and the configuration of the receiving side (reception unit) are shown separated from each other. However, these configurations are shown in this way merely for convenience of description. Therefore, in the first embodiment, both transmission of transmission waves and reception of reception waves are implemented by a single wave transmitter and receiver 210, as described above. However, the technique of the first embodiment is also applicable to a configuration in which the configuration of the transmitting side and the configuration of the receiving side are separated from each other.

In the first embodiment, at least a part of the configuration shown in FIG. 6 is implemented as a result of cooperation between hardware and software, more specifically, as a result of the processor 223 of the object detector 200 reading and executing computer programs from the storage device 222. In the first embodiment, at least a part of the configuration shown in FIG. 6 may be implemented by dedicated hardware (circuitry).

First, the configuration of the transmitting side of the object detector 200 will be briefly described.

As shown in FIG. 6, the object detector 200 includes, as the configuration of the transmitting side, a transmission control unit 430, a wave transmitter 411, a code generation unit 412, a carrier wave output unit 413, a multiplier 414, and an amplifier circuit 415.

The wave transmitter 411 is composed of the transducer 211 described above, and transmits transmission waves according to a transmission signal output from (amplified by) the amplifier circuit 415 by the transducer 211.

In the first embodiment, the wave transmitter 411 encodes, based on the configuration that will be described below, transmission waves into transmission waves containing identification information with a predetermined code length, and then transmits the encoded transmission waves.

The code generation unit 412 generates a pulse signal corresponding to, for example, a code of a bit string that is a sequence of bits, 0s or 1s. The length of the bit string corresponds to the code length of the identification information to be added to a transmission signal. The code length is set to, for example, a length large enough to allow transmission waves that are transmitted from each of the four object detectors 200 shown in FIG. 1 to be distinguished from each other.

The carrier wave output unit 413 outputs a carrier wave that is a signal to which the identification information is to be added. For example, the carrier wave output unit 413 outputs a sine wave with a predetermined frequency as a carrier wave.

The multiplier 414 multiplies the output from the code generation unit 412 and the output from the carrier wave output unit 413 to modulate the carrier wave so that the identification information is added thereto. The multiplier 414 outputs the modulated carrier wave with the identification information added thereto to the amplifier circuit 415 as a transmission signal on which the transmission waves will be based. In the first embodiment, one or a combination of two or more of a plurality of generally well-known modulation methods such as, for example, an amplitude modulation method and a phase modulation method can be used as a modulation method.

The amplifier circuit 415 amplifies the transmission signal output from the multiplier 414 and outputs the amplified transmission signal to the wave transmitter 411.

Referring also to FIG. 3, when the transmission control unit 430 (processor 223) receives from the ECU 100 an ultrasonic wave generation instruction including information on the directivity of ultrasonic waves to be generated, the transmission control unit 430 (processor 223) refers to the directivity correspondence information 230 and selects from the ten electrodes a combination of a voltage application voltage and a ground voltage corresponding to the directivity in the ultrasonic wave generation instruction. The transmission control unit 430 then controls the switching unit 212 according to the combination of a voltage application electrode and a ground electrode in the wave transmitter 411 (transducer 211) to perform switching to connect the wire corresponding to the voltage application electrode out of the ten wires to the power supply, perform switching to connect the wire corresponding to the ground electrode to the ground, and perform switching to insulate the other wires.

With such a configuration, in the first embodiment, transmission waves (ultrasonic waves) with predetermined identification information added thereto can be transmitted and the directivity of the transmission waves can be controlled by using the transmission control unit 430, the switching unit 212, the code generation unit 412, the carrier wave output unit 413, the multiplier 414, the amplifier circuit 415, and the wave transmitter 411.

Next, the configuration of the receiving side of the object detector 200 will be briefly described.

As shown in FIG. 6, the object detector 200 includes, as the configuration of the receiving side, a wave receiver 421, an amplifier circuit 422, a filtering unit 423, a correlation processing unit 424, an envelope processing unit 425, a threshold processing unit 426, and a detection processing unit 427.

The wave receiver 421 is composed of the transducer 211 described above, and receives transmission waves reflected from an object as reception waves by the transducer 211.

The amplifier circuit 422 amplifies a reception signal that is a signal according to the reception waves received by the wave receiver 421.

The filtering unit 423 filters the reception signal amplified by the amplifier circuit 422 to reduce noise. In the first embodiment, the filtering unit 423 may acquire information on the frequency of the transmission signal and may further perform correction of the frequency of the reception signal so as to match the frequency of the transmission signal (e.g., correction using a bandpass filter that passes specific frequencies, correction for a frequency transition due to Doppler shift, etc.)

The correlation processing unit 424 acquires a correlation value corresponding to the degree of similarity in identification information between the transmission waves and the reception waves based on, for example, the transmission signal acquired from the configuration of the transmitting side and the reception signal after filtering by the filtering unit 423. The correlation value can be acquired based on a generally well-known correlation function etc.

The envelope processing unit 425 obtains an envelope of a waveform of a signal corresponding to the correlation value acquired by the correlation processing unit 424.

The threshold processing unit 426 compares the value of the envelope obtained by the envelope processing unit 425 with a predetermined threshold.

The detection processing unit 427 identifies the time at which the signal level of the reception waves reaches a peak higher than the threshold (time t4 shown in FIG. 5) based on the comparison result from the threshold processing unit 426, and detects the distance to an object by using the TOF technique.

Based on the above configuration, the object detection system of the first embodiment performs a process shown in FIG. 8 described below. A series of steps shown in FIG. 8 can be repeatedly performed at, for example, predetermined control cycles. FIG. 8 is a flowchart showing a process that is performed by the object detection system of the first embodiment.

As shown in FIG. 8, in the first embodiment, first, in 51, when the transmission control unit 430 (FIG. 6) receives from the ECU 100 an ultrasonic wave generation instruction including information on the directivity of ultrasonic waves to be generated, the transmission control unit 430 refers to the directivity correspondence information 230, selects from the ten electrodes a combination of a voltage application electrode and a ground electrode corresponding to the directivity in the ultrasonic wave generation instruction, and controls the switching unit 212 according to the combination to perform switching to connect the wire corresponding to the voltage application electrode out of the ten wires to the power supply, perform switching to connect the wire corresponding to the ground electrode to the ground, and perform switching to insulate the other wires.

Next, in S2, the wave transmitter 411 of the object detector 200 transmits transmission waves with predetermined identification information added thereto.

Then, in S3, the wave receiver 421 of the object detector 200 receives reception waves corresponding to the transmission waves transmitted in S2. The correlation processing unit 424 of the object detector 200 starts acquiring a correlation value corresponding to the degree of similarity in identification information between the transmission waves and the reception waves as controlled by, for example, the ECU 100.

Thereafter, in S5, the detection processing unit 427 detects the distance to an object by the TOF technique after the processing by the envelope processing unit 425 and the processing by the threshold processing unit 426.

As described above, according to the wave transmitter and receiver 210 including the transducer 211 and the switching unit 212 in the object detection system of the first embodiment, the directivity of ultrasonic waves can be changed by changing the combination of a voltage application electrode and a ground electrode out of the ten electrodes. Therefore, the directivity of ultrasonic waves can be controlled at low cost.

Since the directivity of ultrasonic waves can be controlled, useful information can be acquired by controlling the directivity of ultrasonic waves when it is desired to identify whether reflected waves are reflected waves from a road surface or reflected waves from an obstacle. Identifying the reflected waves would eliminate the time required to filter unnecessary information (reflected waves from a road surface) in post-processing.

The upper electrode is divided into nine electrodes 4a to 4i (FIG. 3) so that the upper electrode 4E in the center can be selected as a voltage application electrode or a ground electrode. This can make it possible to apply a voltage to the piezoelectric body 6 in various ways and also to control the directivity of ultrasonic waves that are generated from the piezoelectric body 6 in various ways.

Moreover, since the electrodes are disposed on the two opposing surfaces, the directivity can be more easily controlled and design cost can be reduced as compared to the case where the electrodes are disposed on three or more surfaces.

The transducer needs to have at least a predetermined size in order to vibrate. Therefore, when a plurality of transducers is used to control the directivity of ultrasonic waves in the related art, it is necessary to use a plurality of transducers having at least the predetermined size, which increases cost. On the other hand, according to the technique of the first embodiment, the directivity of ultrasonic waves can be controlled with a single transducer 211. Therefore, cost can be reduced.

### Second Embodiment

Next, a second embodiment will be described. Description of the matters similar to those of the first embodiment will be omitted as appropriate. The second embodiment illustrates a case where ultrasonic waves with two or more directivities are simultaneously generated from the transducer 211.

The directivity correspondence information 230 shown in FIG. 7 stores correspondence information between the combination of a voltage application electrode and a ground voltage out of the ten electrodes when ultrasonic waves with two or more directivities are to be generated and the two or more directivities.

When the control unit 220 (FIG. 2) receives from the ECU 100 an ultrasonic wave generation instruction including information on two or more directivities of ultrasonic waves to be generated, the control unit 220 performs control to refer to the directivity correspondence information 230, select from the three or more electrodes a combination of a voltage application electrode and a ground electrode corresponding to the two or more directivities in the ultrasonic wave generation instruction, and apply an alternating voltage to the voltage application electrode to generate ultrasonic waves with the two or more directivities.

In this case, the control unit 220 performs control to generate ultrasonic waves with two or more directivities by making either or both of the frequency and phase of the ultrasonic waves different from each other. When the control unit 220 detects ultrasonic waves via the wave transmitter and receiver 210 immediately thereafter, the control unit 220 identifies which of the ultrasonic waves of the two or more directivities are the original ultrasonic waves of the reflected waves, based on the frequency or phase of the detected ultrasonic waves, whichever has been made different.

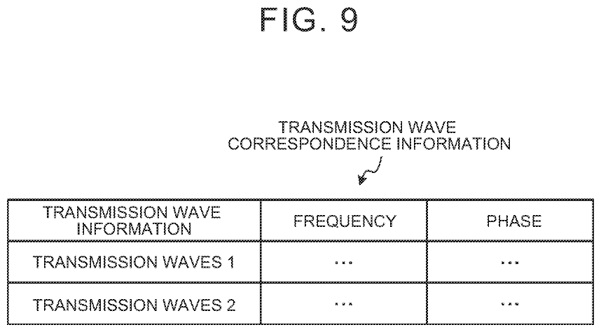

FIG. 9 is a diagram showing transmission wave correspondence information of the second embodiment. The transmission wave correspondence information is stored in the storage device 222 (FIG. 2). As shown in FIG. 9, assuming that ultrasonic waves with two directivities to be generated simultaneously are transmission waves 1, 2, different frequencies and phases are associated with the transmission waves 1, 2. In this way, when the control unit 220 detects ultrasonic waves via the wave transmitter and receiver 210 immediately after generating the ultrasonic waves with two directivities, the control unit 220 can identify, based on the frequency and phase of the detected ultrasonic waves, which of the ultrasonic waves with two or more directivities are the original ultrasonic waves of the reflected waves.

According to the second embodiment, ultrasonic waves with two or more directivities can thus be simultaneously generated by selecting a combination of a voltage application electrode and a ground electrode from the three or more electrodes.

When reflected waves of the ultrasonic waves with two or more directivities are detected, which of the ultrasonic waves with two or more directivities are the original ultrasonic waves of the reflected waves can be identified based on the frequency and phase.

Simultaneously transmitting ultrasonic waves with two or more directivities and identifying the original ultrasonic waves upon reception can reduce an abrupt decrease in signal strength due to multipath that is caused by obstacles with a plurality of reflection points.

Although the embodiments and modifications of the present disclosure are described above, the above embodiments and modifications are merely illustrative and are not intended to limit the scope of the invention. The above novel embodiments and modifications can be carried out in various forms, and various omissions, replacements, and changes can be made without departing from the spirit and scope of the invention. The above embodiments and modifications are included in the scope and gist of the invention, and are included in the scope of the invention described in the claims and equivalents thereof.

For example, the above embodiments illustrate an example in which the upper electrode 4 is divided into nine electrodes and the whole electrode and the individual electrodes are rectangular. However, the present invention is not limited to this. The whole electrode or the individual electrodes may have a shape other than a rectangle (triangle, circle, etc.), and the upper electrode may be divided into any number of electrodes other than nine.

The lower electrode 7 may be divided into two or more electrodes.

The directivity correspondence information 230 (correspondence information) may be stored in a storage device external to the object detector 200.

### DESCRIPTION OF THE REFERENCE NUMERALS

1: vehicle, 4: upper electrode, 5: wire, 6: piezoelectric body, 7: lower electrode, 8: wire, 100: ECU, 200: object detector, 210: wave transmitter and receiver, 211: transducer, 212: switching unit, 220: control unit, 221: input and output device, 222: storage device, 223: processor, 230: directivity correspondence information

1. An ultrasonic generator comprising:
a transducer including a piezoelectric body that vibrates due to a piezoelectric effect and generates ultrasonic waves when an alternating voltage is applied, and three or more electrodes provided in different regions on a surface of the piezoelectric body; and
a control unit that, when the control unit receives an ultrasonic wave generation instruction including information on a directivity of ultrasonic waves to be generated, performs control to select from the three or more electrodes a combination of a voltage application electrode and a ground electrode corresponding to the directivity in the ultrasonic wave generation instruction and apply the alternating voltage to the voltage application electrode to generate ultrasonic waves, the voltage application electrode being an electrode to which the alternating voltage is to be applied, and the ground electrode being an electrode to be at a ground potential.

2. The ultrasonic generator according to claim 1, further comprising
a storage unit that stores correspondence information between the combination of the voltage application electrode and the ground electrode out of the three or more electrodes and the directivity of the ultrasonic waves to be generated, wherein
the control unit performs control to refer to the correspondence information and generate the ultrasonic waves.

3. The ultrasonic generator according to claim 2, wherein
the storage unit stores, as the correspondence information, the combination of the voltage application electrode and the ground electrode out of the three or more electrodes when ultrasonic waves with two or more directivities are to be generated and the two or more directivities, and
when the control unit receives an ultrasonic wave generation instruction including information on the two or more directivities of the ultrasonic waves to be generated, the control unit performs control to refer to the correspondence information, select from the three or more electrodes the combination of the voltage application electrode and the ground electrode corresponding to the two or more directivities in the ultrasonic wave generation instruction, and apply the alternating voltage to the voltage application electrode to generate ultrasonic waves with the two or more directivities.

4. The ultrasonic generator according to claim 3, wherein the control unit simultaneously transmits the ultrasonic waves with the two or more directivities.

5. The ultrasonic generator according to claim 1, wherein
out of the three or more electrodes, at least two electrodes are disposed on a first surface of the piezoelectric body, and at least one electrode is disposed on a second surface opposing the first surface,
the control unit selects at least one of the electrodes disposed on the first surface as the voltage application electrode, and selects the electrode disposed on the second surface as the ground electrode, and
the control unit controls the directivity of the ultrasonic waves to be generated by switching the electrode that serves as the voltage application electrode among the electrodes disposed on the first surface.

6. A transducer, comprising:
a piezoelectric body that vibrates due to a piezoelectric effect and generates ultrasonic waves when an alternating voltage is applied; and
three or more electrodes provided in different regions on a surface of the piezoelectric body, in which a directivity of the ultrasonic waves that are generated is different depending on a selected combination of a voltage application electrode and a ground electrode, the voltage application electrode being an electrode to which the alternating voltage is to be applied, and the ground electrode being an electrode to be at a ground potential.

7. An object detector in which a transmission unit transmits ultrasonic waves from a transducer and a reception unit receives reflected waves of the ultrasonic waves by the transducer, wherein
the transducer includes
a piezoelectric body that vibrates due to a piezoelectric effect and generates ultrasonic waves when an alternating voltage is applied, and
three or more electrodes provided in different regions on a surface of the piezoelectric body, in which a directivity of the ultrasonic waves that are generated is different depending on a selected combination of a voltage application electrode and a ground electrode, the voltage application electrode being an electrode to which the alternating voltage is to be applied, and the ground electrode being an electrode to be at a ground potential,
the transmission unit includes a switching unit that changes the combination of the voltage application electrode and the ground electrode,
the reception unit includes an amplifier circuit and a filtering unit, and
the filtering unit acquires information on a frequency of a transmission signal, and performs correction of a frequency of a reception signal so as to match the frequency of the transmission signal.

8. The object detector according to claim 7, comprising
a storage unit that stores correspondence information between the combination of the voltage application electrode and the ground electrode out of the three or more electrodes and the directivity of the ultrasonic waves to be generated, wherein
the transmission unit refers to the correspondence information and controls the switching unit to transmit the ultrasonic waves from the transducer.

9. The object detector according to claim 8, wherein
the storage unit stores, as the correspondence information, the combination of the voltage application electrode and the ground electrode out of the three or more electrodes when ultrasonic waves with two or more directivities are to be generated and the two or more directivities, and
when the transmission unit receives an ultrasonic wave generation instruction including information on the two or more directivities of the ultrasonic waves to be generated, the transmission unit refers to the correspondence information, selects from the three or more electrodes the combination of the voltage application electrode and the ground electrode corresponding to the two or more directivities in the ultrasonic wave generation instruction, controls the switching unit to apply the alternating voltage to the voltage application electrode to generate the ultrasonic waves with the two or more directivities, and transmits the ultrasonic waves from the transducer.

10. The object detector according to claim 7, wherein
the transmission unit performs control to generate ultrasonic waves with two or more directivities by making at least one of a frequency, a phase, and an amplitude of the ultrasonic waves different from each other, and
when the reception unit detects ultrasonic waves via the transducer immediately thereafter, the reception unit identifies which of the ultrasonic waves of the two or more directivities are the original ultrasonic waves of reflected waves, based on the frequency, the phase, or the amplitude of the detected ultrasonic waves, whichever has been made different.

11. The object detector according to claim 10, wherein
the transmission unit simultaneously transmits the ultrasonic waves with the two or more directivities, and
when the reception unit detects ultrasonic waves via the transducer immediately thereafter, the reception unit identifies which of the ultrasonic waves of the two or more directivities are the original ultrasonic waves of reflected waves, based on the frequency, the phase, or the amplitude of the detected ultrasonic waves, whichever has been made different.
